(19) United States
(12) Patent Application Publication
(10) Pub. No.: US 2022/0229102 A1
(43) Pub. Date: Jul. 21, 2022

(54) ELECTRICAL ARC FLASH MITIGATION SYSTEM

(71) Applicant: Russell Lee Ebersole, Hagerstown, MD (US)

(72) Inventor: Russell Lee Ebersole, Hagerstown, MD (US)

(21) Appl. No.: 17/151,148

(22) Filed: Jan. 16, 2021

(51) Int. Cl. G01R 31/12; H02H 1/00

(52) U.S. Cl. CPC G01R 31/1218; H02H 3/16; H02H 1/0015

(57) ABSTRACT

The present invention includes devices and systems which detect an are flash electrical fault by calculating the rate of change in ultraviolet light, infrared light, and electrical current. This ensures compliance of plant electrical systems with 29 U.S.C. § 651 et seq. (1970), 29 CFR § 1910333, NFPA 70E and IEEE 1584 Standard. The devices and systems simultaneously provide a means for maintenance personnel to reduce long time, long time delay, short time, short time delay, instantaneous, ground fault, ground fault delay, and trip functions in the electronic trip units of typical low voltage breakers from a remote location outside the arc flash boundary. The devices and systems can also be controlled from a cloud-based computer which can be the host for the system operating software.

### BACKGROUND OF THB INVENTJON

### Field of the Invention

The present invention is an electronic system that calculates the rate of change associated with ultraviolet light, infrared light and electrical current in a low voltage (690 volts or less) electrical system associated with the arc Hash incident energy that accompanies a three-phase bolted fault and the signaling and control of up-stream, medium voltage (2300 volt through 34.5 kilovolt) electrical systems to mitigate electrical equipment damage and injury to personnel in the vicinity of an arc flash event.

The present invention is distinct when compared to current art in that it provides protection for both the electrical equipment in the substation room and remote electrical systems being worked on by humans throughout the plant simultaneously.

The present invention also allows human interface with the are flash mitigation system to reduce the amount of instantaneous, ground fault, short time, and long time energy from a remote location located outside the arc flash boundary where exposure to the electrical fault could produce damage to the electrical equipment and/or personal injury.

### Description of the Present Invention

With the availability of faster central processing units (CPUs), computers can now be programmed to detect and signal an excessive rate of change per unit of time of ultraviolet light arriving (duv/dt) during an arc flash event. This can be accomplished by the installation of the present invention near electrical equipment susceptible to an arc flash event. The system can also be installed remotely in a Class 1A datacenter via a high-speed internet connection to the cloud. Computers can now be programmed to detect and signal an excessive rate of change per unit of time of infrared light arriving (dir/dt) during an arc flash event. Computers can also be programmed to detect and signal an excessive rate of change per unit of time of electrical current changing magnitude (di/dt) during an arc flash event. Light travels through empty space at 186,000 miles per second. Electricity travels through the conductors of an industrial facility at 60-80% of the speed of light due to circuit impedance and other inherent resistance along the current path. Because it is not travelling through free space, the electricity which flows through the wires in a typical industrial facility travels only about 1/100th the speed of light. Traditional ultraviolet light, infrared light and electrical current detection systems rely on arriving at a set point before they signal a condition requiring interruption of the electrical circuit (e.g., ultraviolet light, infrared light, and current trip point), rendering them comparatively slow as they are dependent on the elapse of time. The present invention only requires a significant increase in the rate of change of these three variables per unit time to signal the imminent arrival of damaging arc flash incident energy.

Modern day computers are available with 128 core processors and are capable of operating at over 200 Gigahertz master clock operating speeds, thus making them capable of performing in excess of 1 Million calculations per second. This capability enables them to calculate duv, dir, and di calculations to determine variations in the rate of change of these variables. These rapid changes in the duv, dir and di can be programmed to open or trip the up-stream interrupting device while the magnitude of the short circuit or ground fault energy is very low. The present invention allows interruption of the formation of arc flash incident energy which can damage equipment or result in personal injury, thus limiting its magnitude to a value where there is little to no damage or injury.

The Institute of Electrical and Electronic Engineers (IEEE) has demonstrated the average duration of a typical arc flash event to last two (2) seconds and the duration associated with clearing the fault by an up-stream modern vacuum contactor circuit breaker to be three (3) or five (5) cycles. At the end of three (3) or five (5) cycles, the breaker has completely opened, and any electrical arc drawn across the contacts of the vacuum bottle has completely extinguished. The present invention is capable of detecting the inception of an impending arc flash event and providing signaling to an up-stream trip coil within 1.66 cycles of calculating an increase in the rate of change of the duv, dir and di which exceeds the user set limits.

The user can set the duv, dir, and di values to allow clearance of typical coil magnetizing current in such equipment as transformers, motors, and other devices which encompass larger electrical coils. As an example, typical modern dry-type transformers will draw 6 to 8 times full load Amps of magnetizing current upon initial energization. Once the coils have been energized, they are capable of discharging transformer through-fault, or transformer secondary side fault current equal to their base-rated full load Amps divided by their nameplate impedance. As an example, for a typical 2000 kVA rated transformer applied in a 480V system, the magnetizing current is approximately eight times 2400 Amps or 19,200 Amps. Conversely, this same transformer is capable of delivering 2400 Amps divided by its nameplate impedance of 5.75 percent, resulting in approximately 41,838 Amps of transformer through-fault, or transformer secondary side fault current. During an are flash event, the short circuit current rises to the maximum that can be delivered by magnetic coils within the electrical system (from transformers, motors, generators, etc.) in one second (60 cycles), resulting in the initiation of phase changes (solid to a liquid, and liquid to a gas), releasing extremely large amounts of latent energy which results in the generation of large balls of flame, explosions, and destruction of conductors within the electrical equipment. FIG. 1 is a picture demonstrating the key hazards which can occur during the two second duration of an arc flash incident:

The present invention is capable of detecting the onset of the arc flash incident energy and interrupting electrical current flow via a trip signal to the up-stream circuit breaker within 0.11666 seconds, or 7 cycles. This includes the 5-cycle breaker clearing time associated with a modern day vacuum interrupting circuit breaker. FIG. 2 demonstrates the reduction of arc flash energy by the present invention.

The present invention is designed to detect and signal the impending are flash event within 2.4 milliseconds to a downstream breaker trip coil. A lock-out relay is installed on another set of high-speed contacts which feeds the opening circuit of the present invention to prevent remote closure of the interrupting circuit breaker without proper investigation of the cause of the arc flash event. The lock-out relay is an important safety feature. The opening signal from the lock-out relay arrives at the breaker trip coil approximately 0.6 seconds after the initial trip signal due to the operating time of the lock-out relay. The lock-out relay does not add to the operating time of the system because the trip coil has already received the signal to open. Once the system energizes the breaker trip coil, three (3) or five (5) cycles are required (depending on the breaker manufacturer) for the breaker to open and extinguish the are flash event. The operating time of the system is within the 7-cycle timeframe, thus preventing the electrical conductors from entering the phase changes which produce plasma, explosions, equipment destruction and hazard to personal safety.

The present invention also includes an arc flash breaker settings control system (ABC System). Many trip units installed on air magnetic circuit breakers include the ability to shift from “NORMAL” to “MAINTENANCE” settings for the long time, long time delay, short time, short time delay, instantaneous, and ground fault (LSIG) protective functions. This feature allows the breaker to function with a high degree of reliability when the NORMAL settings group is selected. When the NORMAL settings group is selected, the protective functions are set to the highest level permitted by the electrical system's power system study and arc flash analysis, predominately protecting only the equipment installed in the plant's electrical distribution system. Thus, the breaker is not subject to inadvertent or spurious tripping as electrical loads are energized or deenergized. This does not necessarily provide appropriate protection from high arc flash incident energies to humans working on branch circuits of the electrical distribution system. As an example, the instantaneous protective trip function may be set to eleven (11) times the trip unit rating plug setting (3200 Amps×11=35,200 Amps) when in the NORMAL mode which is good for equipment protection and reliability but extremely hazardous to maintenance personnel working down-stream on the plant's electrical distribution system. Conversely, with the breaker in the MAINTENANCE mode, the instantaneous protective trip function may be set to two (2) times the trip unit rating plug setting (e.g., 3200 Amps×2=7,000 Amps), providing maximum protection to maintenance personnel working on the down-stream of the plant's electrical distribution system.

The present invention allows the user to switch between the NORMAL and MAINTENANCE functions from a remote location outside the area where the arc flash event might occur. This feature allows maintenance personnel to activate the MAINTENANCE mode remotely without having to enter the arc flash boundary. The ABC System is comprised of a 120V to 24V AC control power transformer which supplies power to a power distribution block. The 24 VAC power distribution block supplies power to individual selector switches for each breaker in the electrical equipment (e.g., switchgear) which is equipped with connectivity to the ABC System. The selector switches are contained on a hinged panel located behind a pad lockable front door to allow the installation of a padlock for Lock-Out-Tag-Out (LOTO) purposes once any breaker in the system is put into the MAINTENANCE mode. From the output of each selector switch, power flows to a 24V AC blue push-to-test (PTT) pilot light. There is an individual pilot light for each breaker installed in the electrical equipment. The push-to-test feature allows maintenance personnel to verify the pilot light is functional, even if it is not selected and in the OFF position. The pilot light for each breaker is installed on the exterior of the front door of the cabinet and allows maintenance personnel to see which breakers are in the MAINTENANCE mode, even if a LOTO lock has been installed. The output from an auxiliary contact on the push-to-test pilot lights are connected to a remote input/output (I/O) terminal block. This remote I/O block functions as a miniature programmable logic controller. Upon receiving the 24V signal from the PTT pilot light, the remote I/O terminal block converts the voltage to a serial word. The serial word is in turn routed via TCPIP and Cat. VI cable to a larger programmable logic controller (PLC). The PLC is remotely mounted up to three hundred feet or more away from the remote I/O block. This placement allows the breakers in the electrical equipment to be remotely controlled from outside of the arc flash boundary. The Main PLC part of the ABC System (MPP) receives input from the Maintenance Interface part of the ABC System (MIP) and routes it to the Electrical Equipment Interface part of the ABC System (EIP) which is located directly beside the electrical equipment and inside the arc flash boundary. This part of the system is also connected via a Cat. VI cable to another remote input/output (I/O) terminal block and provides direct interface to the breaker's trip unit. This remote I/O terminal block provides 24V AC to the breaker's trip unit which in turn allows it to be switched from the NORMAL to the MAINTENANCE modes. All power supplys in the ABC System are monitored and a yellow PTT pilot light is illuminated in the event of a failure.

### Reliability of the Present Invention

The following features of the present invention ensure a high degree of reliability. The present invention receives current information from a specially designed Class C-100 current transformer (CT) pack which encompasses a window for each individual phase (Phase A. Phase B, and Phase C) in a single rectangular unit which is of an extremely thin design, allowing placement behind the line side run backs of the main breaker of a typical metal clad, metal enclosed low voltage switchgear lineup. The current transformer pack is rated to the maximum current flow allowable through the main breaker of the switchgear lineup (e.g., 2500 Amps, 3200 Amps, 4000 Amps, etc.) The secondary of the specialized current transformer pack is rated for 1 Amp. Typical ratings for the custom transformer packs are 2500 Amps/1 Amp, 3200 Amps/1 Amp, and 4000 Amps/1 Amp, meaning when 2500 Amps, 3200 Amps, or 4000 Amps flow through the main switchgear bus or breaker, 1 Amp will flow into the present invention, providing input to the di/dt calculator. To further elaborate on this feature, assuming 1600 Amps are flowing through the main bus or breaker, a 3200 Amp/1 Amp current transformer pack will have an output of 0.5 Amps. Once this value arrives at the di/dt calculator, it is run through an analog to digital convertor which feeds a corresponding digital signal to the CPU. In turn, the CPU, using IEEE 1584 Standard via conventional calculus, calculates the rise/run of the current signal and then takes its tangent to determine the rate of change of unit time. This value is compared to the tangent of normal in-rush values associated with transformer windings, motor windings, etc. If a significant positive change is determined to exist, the di/dt calculator sends a trip signal to an AND gate awaiting signals from the duv/dt and dir/dt calculators. If all three signals into the AND gate are met, the CPU sends a trip initiation signal to multiple down-stream static switches which in turn send a trip signal to the up-stream circuit breaker interrupting device. This will trip the circuit breaker and interrupt the arc flash incident energy within seven (7) cycles.

In the present invention, the secondary outputs of the current transformer pack are routed to a 3-phase current transformer shorting block before reaching the analog to digital convertors of the CPU. Using the shorting block, the current transformer pack can be shorted, allowing the injection of adjustable secondary currents from a test set. This allows online testing of the di/dt calculator while the unit is energized and operating. The CT shorting block also contains a disconnecting provision which interrupts the trip signal to the up-stream circuit breaker disconnecting device's trip coil. Setting the current testing device to a value slightly higher than the user defined maximum expected magnetizing current generated by the substation's transformer and low voltage motors will trip the current calculator as it sees current rise (di/dt) from zero (test set “off”) to the test value upon energization of the testing circuit. This allows surveillance testing of the di/dt function while the substation is energized for maximum reliability.

The light intensity of an arc flash 3 meters from the source is over 1 million lux, and a more recent arc flash test recorded 13.1 million lux-approximately 130 times brighter than direct sunlight (ultraviolet and infrared.) The present invention receives ultraviolet light information from a specially designed UV/IR detector. The UV/IR detector captures a rise in the amount of ultraviolet light (units of millijoules per square centimeter—mJ/cm²) This is the ultraviolet energy received per unit area in a given time associated with an arc flash event inside switchgear or other electrical equipment. Multiple UV/IR detectors may be installed in the transformer enclosure, the main breaker compartment, the main horizontal bus area, and feeder breaker outgoing cable compartments. In reference to ultraviolet light, these detectors provide input (mJ/cm² to the duv/dt calculator. Once these values arrive at the duv/dt calculator, they are run through analog to digital convertors which feed corresponding digital signals to the CPU. In turn, the CPU, using conventional calculus, calculates the rise/run of the ultraviolet signal, then takes its tangent to determines the rate of change per unit time. This value is compared to the tangent of ambient light inside switchgear or other electrical equipment enclosures. If a significant positive change is determined to exist, the duv/dt calculator sends a trip signal to an AND gate awaiting signals from the duv/dt calculator. If all three (di/dt, duv/dt, and dir/dt) signals into the AND gate are met, the CPU sends a trip initiation signal to multiple down-stream static switches which in turn sends a trip signal to the electrical system's up-stream circuit breaker's trip coil. This will trip the circuit breaker and interrupt the arc flash incident energy within seven (7) cycles. Using the flashlight function of a personal cell phone to send bright light to the UV/IR detector, an arc flash event can be simulated. Providing this light input at the same time that the di/dt current calculator is in test mode with the current simulated to be above normal in-rush values will trip the present invention and thus allow routine surveillance testing anytime the user desires. Setting the current testing device to a value slightly higher than the user defined maximum expected magnetizing current generated by the substation's transformer and low voltage motors will trip the current calculator as it sees current rise (di/dt) from zero (test set “off”) to the test value upon energization of the testing circuit. When a cellular phone's flash is added at the same time current from the test set is rising (increasing di/dt), the user can simulate an actual arc flash event without causing a trip of the up-stream electrical system's feeder breaker. This allows surveillance testing of the di/dt, duv/dt, and dir/dt functions while the substation is energized for maximum reliability.

The present invention also receives infrared light information from a specially designed UV/IR detector. The UV/IR detector captures a rise in the amount of infrared light (watts/M²) which is the energy produced by an infrared light source over a specific area. This is the infrared energy received per unit area in a given time associated with an arc flash event inside switchgear or other electrical equipment. Multiple UV/IR detectors may be installed in the transformer enclosure, the main breaker compartment, the main horizontal bus area, and feeder breaker outgoing cable compartments. In reference to infrared light, these detectors also provide input (watts/M²) to the dir/dt calculator. Once these values arrive at the dir/dt calculator, they are run through analog to digital convertors which feed corresponding digital signals to the CPU. In turn, the CPU, using conventional calculus, calculates the rise/run of the infrared signal. then takes its tangent to determine the rate of change per unit time. This value is compared to the tangent of ambient light inside switchgear or other electrical equipment enclosures. If a significant positive change is determined to exist, the dir/dt calculator sends a trip signal to an AND gate awaiting signals from the dir/dt calculator. If all three (di/dt, duv/dt, and dir/dt) signals into the AND gate are met, the CPU sends a trip initiation signal to multiple down-stream static switches which in turn sends a trip signal to the electrical system's up-stream circuit breaker's trip coil. This will trip the circuit breaker and interrupt the arc flash incident energy within seven (7) cycles. Using the flashlight function of a personal cell phone to send bright light to the UV/IR detector, an arc flash event can be simulated. Providing this light input at the same time the di/dt current calculator is in test mode with the current simulated to be above normal in-rush values will trip the present invention and thus allow routine surveillance testing anytime the user desires. Setting the current testing device to a value slightly higher than the user defined maximum expected magnetizing current generated by the substation's transformer and low voltage motors will trip the current calculator as it sees current rise (di/dt) from zero (test set “off”) to the test value upon energization of the testing circuit. When a cellular phone's flash is added at the same time current from the test set is rising (increasing di/dt), the user can simulate an actual arc flash event without causing a trip of the up-stream electrical system's feeder breaker. This allows surveillance testing of the di/dt, duv/dt, and dir/dt functions while the substation is energized for maximum reliability.

The term “electronic” comprises any electrical device connected to a circuit board via control wiring or circuit board tracing that conducts low voltage signals or current through electronic components and devices such as resistors, rectifiers, computer chips, capacitors, invertors, transistors, tubes, potentiometers, relays, switching devices, static switches, current transformers, infrared detectors, ultraviolet light detectors, Amplifiers, signal generators, digital counters, power supplies, lock out relays, trip coils, diodes, sensors, transformers, fuses or other circuit protection devices, speakers, push buttons, proximity devices, motion sensors and microphones. Electric devices provide interface between discrete inputs and outputs operated by humans or computer processors.

The term “low voltage electrical system” comprises any electrical system which operates at a voltage of 690 volts alternating current (VAC) or less. The operating frequency may be either 50 Hz or 60 Hz. The system may be applied on either three-phase or single-phase systems. The current IEEE 1584 Standard only deals with 3-phase faults. The present invention is unique in that it can be applied to single-phase systems as well even though the single-phase systems have not been fully lab tested yet and are not part of the IEEE 1584 Standard. Examples of low voltage electrical systems include, but are not limited to, primary or secondary unit substations consisting of, but not limited to, a step-down transformer (e.g., ′, a transformer that reduces medium voltage to a lower utilization voltage) and a secondary electrical distribution system such as switchgear, switchboard, power distribution panels or similar equipment. Low voltage distribution systems may also include variable speed alternating current (VAC) and variable speed direct current (VDC) regenerative drives and drive systems. Low voltage loads are typically 24-690 VAC which are the alternating current utilization voltages used in most residential, commercial, and industrial buildings and equipment. 230-760 VDC are the direct current utilization voltages used in most residential, commercial, and industrial buildings and equipment. Medium voltage loads are typically 691-34,500 VAC which are the alternating current utilization voltages used in most commercial and industrial buildings and for powering equipment. Transmission voltage loads are typically 34.5 kV to 750,000 VAC which are the alternating current utilization voltages used in most utility grade transmission and distribution systems throughout the world.

The term “signaling” may refer to any electrical device which generates either an analog or digital signal which then travels from the first device to another through the atmosphere or via an electrical conductor silicone sand, microwave signal, fiberoptic conductor or other transmission or communications medium or path for the purpose of transmitting or receiving information from one device to another.

The term “arc flash event” comprises any condition in which an electrical system begins to experience a transition from one phase (solid, liquid, gas/vapor) to another as a result of the introduction of significant electrical energy into its associated electrical conductors (e.g., aluminum, copper, bismuth, tin, silver, etc.) (see FIG. 1 above)

No admission is made that any reference, including any patent or patent document, cited in this specification constitutes prior art. It will be understood that, unless otherwise stated, reference to any document herein does not constitute an admission that any of these documents forms part of the common general knowledge in the art in United States of America or in any other country. The discussion of the references states what their authors assert, and the applicant reserves the right to challenge the accuracy and pertinency of any of the documents cited herein.

### SUMMARY OF THE INVENTION

Congress passed the Occupational Safety and Health Act of 1970, defining a continuing general duty for employers to provide a safe and hazard free workplace. The Act is codified as 29 U.S.C. § 651 et seq. (1970). 29 CFR § 1910.333 further defines the treatment of electrical hazards in the workplace. 29 CFR § 1910.333 defines NFPA 70E as the consensus standard industrial facilities should use in analyzing their plants' electrical distribution systems for compliance with federal law. NFPA 70E, in turn, provides reference to IEEE 1584 Standard (2002 and 2018 editions). This provides detailed technical methodology for the analysis of plant electrical distribution systems and the calculation of electrical faults, breaker coordination, and arc flash energies.

The present invention addresses the needs described above. The present invention comprises devices or systems that provide early detection and mitigation of an impending arc flash event. In preferred embodiments, the present invention comprises devices which detect the change in ultraviolet light, infrared light, and electrical current in electrical equipment at the onset of an arc flash event. The devices and systems compare these rates of change in ultraviolet light, infrared light, and electrical current against normal rates of change associated with typical in-rush values occurring when energizing electrical equipment and ambient room lighting. In the event that a change in ultraviolet light, infrared light, and electrical current simultaneously exceeds the normal user defined values, the devices and systems send a trip signal to a lock-out relay and to the trip coil of the up-stream medium or low voltage breaker or circuit interrupting device. Due to the speed of operation, the devices and systems are capable of interrupting fault current forming at the contacts of the medium or low voltage circuit breakers or interrupting devices. Breaking the current path within the medium or low voltage circuit breakers results in arc flash incident energies far smaller than allowing the undetected flow of current to continue for two (2) seconds, the normal duration of an arc flash incident.

The devices and systems are specially adapted for the detection of ultraviolet light, infrared light, and electrical current in low voltage electrical equipment where the arc flash incident energy is much higher. Opening the up-stream breaker in the medium voltage system greatly reduces the potential for damage as the medium voltage system delivers a proportionally lower value of current during an arc flash event. The medium voltage breaker is typically more robust due to the application of vacuum bottle technology. Reduction in the amount and duration of fault current associated with the arc flash event reduces the potential for phase change of conductors and other metallic components. Eliminating the potential for phase change stops the arc flash energy from reaching the point where latent heat is produced, destroying conductors and significantly damaging electrical equipment. The devices and systems also provide a mechanism for maintenance personnel or system operators to lower their personal arc flash energy exposure while working on feeder branches of the electrical distribution system. The operation of this part of the system is conducted from outside the arc flash boundary and typically outside the electrical equipment room. The devices and systems provide instant feedback via the illumination of a blue push-to-test pilot light. The pilot light advises personnel that the electrical hazard has been reduced in the circuit they have selected. The devices and systems communicate that the breaker has been placed in the MAINTENANCE mode to an electronic supervisory system which can be monitored remotely and provide event and alarm logging if the breaker is in MAINTENANCE mode for an extended period of time. Event and alarm information is transmitted via a Cat. IV cable to an onboard Ethernet switch located in the Electrical Equipment Interface part of the ABC System (EIP). The Ethernet switch is in turn connected via a fiberoptic isolation device to the facility's computer system and then to the internet. The Electrical Equipment Interface part of the ABC System (EIP) also collects information on metered variables (i.e., Amps, Volts, kW, kWh, etc.) and transmits this information to the facility's computer and then to the internet. This part of the Electrical Equipment Interface part of the ABC System (EIP) displays both the NORMAL and MAINTENANCE settings for long time, long time delay, short time, short time delay, instantaneous, ground fault, and ground fault delay protective functions in the electronic trip units of typical low voltage breakers.

The foregoing summary has outlined some features consistent with the present invention in order that the enclosed herein description thereof may be better understood, and in order that the present contribution to the art may be better appreciated. The present invention is not limited in its application, details, or components merely to those set forth in the following description and illustrations. Devices consistent with the present invention are capable of other embodiments. Also, the phraseology and terminology employed herein are for the purpose of description and should not be regarded as limiting unless explicitly stated as such.

Those skilled in the art will appreciate that the conception upon which this disclosure is based may readily be utilized as a basis for designing of other structures, methods, and systems for carrying out the several purposes of the present invention. It is important, therefore, that the claims be regarded as including such equivalent constructions insofar as they do not depart from the spirit and scope of the devices consistent with the present invention.

### DESCRIPTION OF THE DRAWINGS AND PICTURES

FIG. 1 is a picture demonstrating the key hazards which can occur during the two second duration of an arc flash incident.

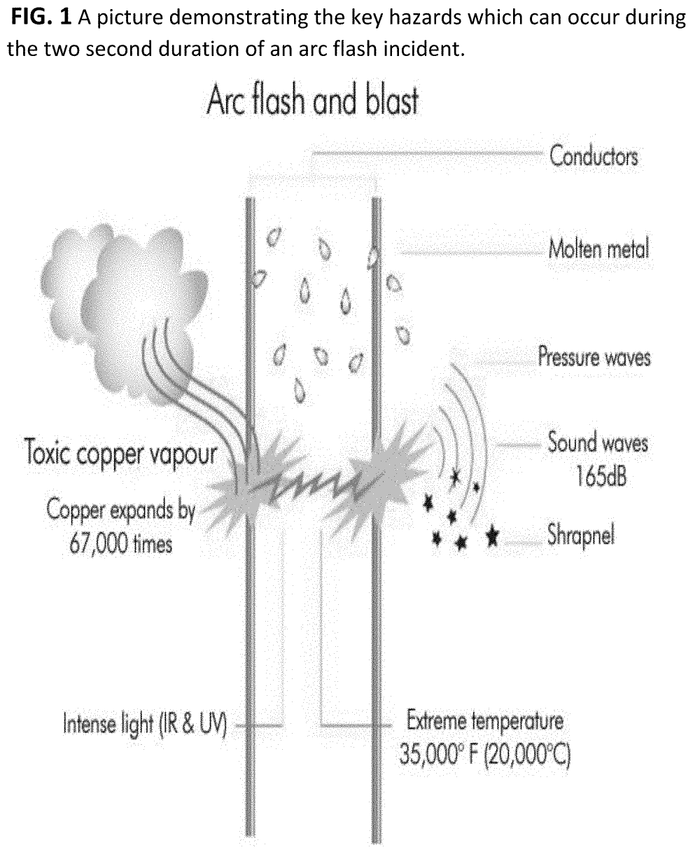

FIG. 2 is a graph illustrating the reduction of arc flash energy by the present invention.

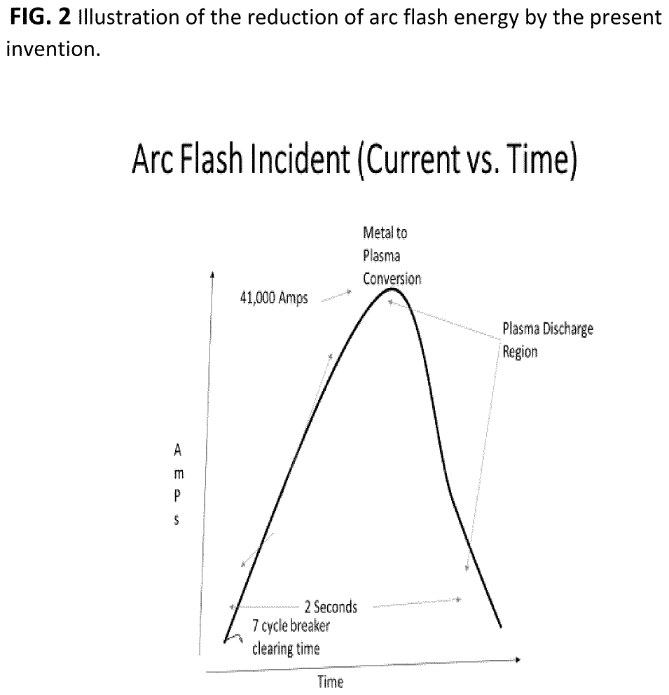

FIG. 3 are perspective views of a first embodiment of the Maintenance Interface part of the ABC System (MIP) (Exterior View of the Front Door and Interior View of the Cabinet.)

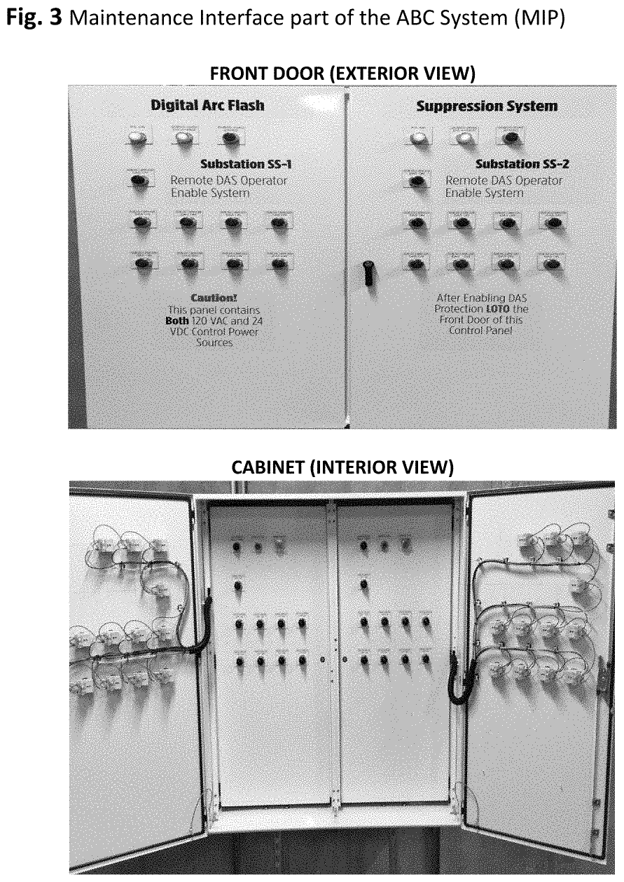

FIG. 4 are perspective views of a first embodiment of the Main PLC part of the ABC System (MPP) (Exterior View of the Front Door and Interior View of the Front Door).

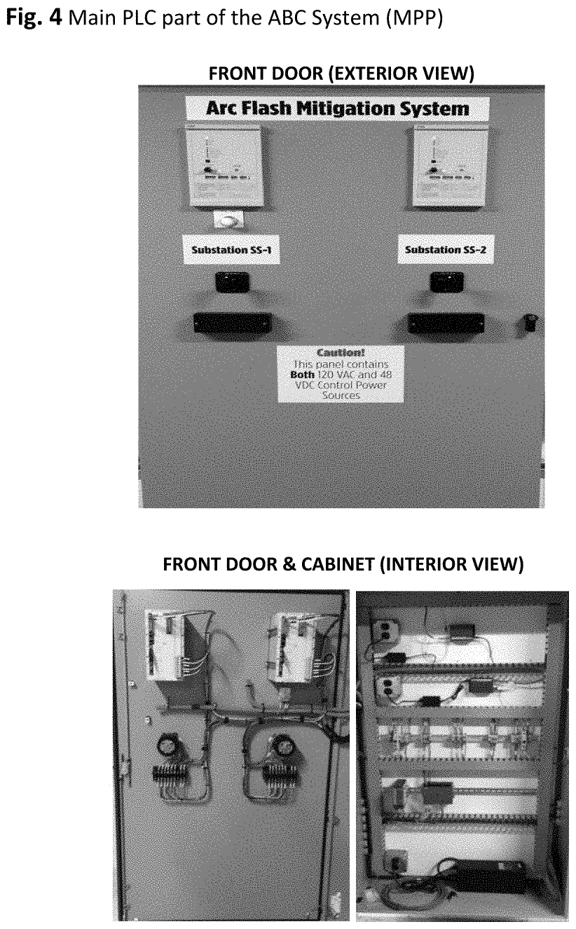

FIG. 5 are perspective views of a first embodiment of the Electrical Equipment Interface part of the ABC System (EIP) (Interior View of the Front Door and Exterior View of the Front Door.)

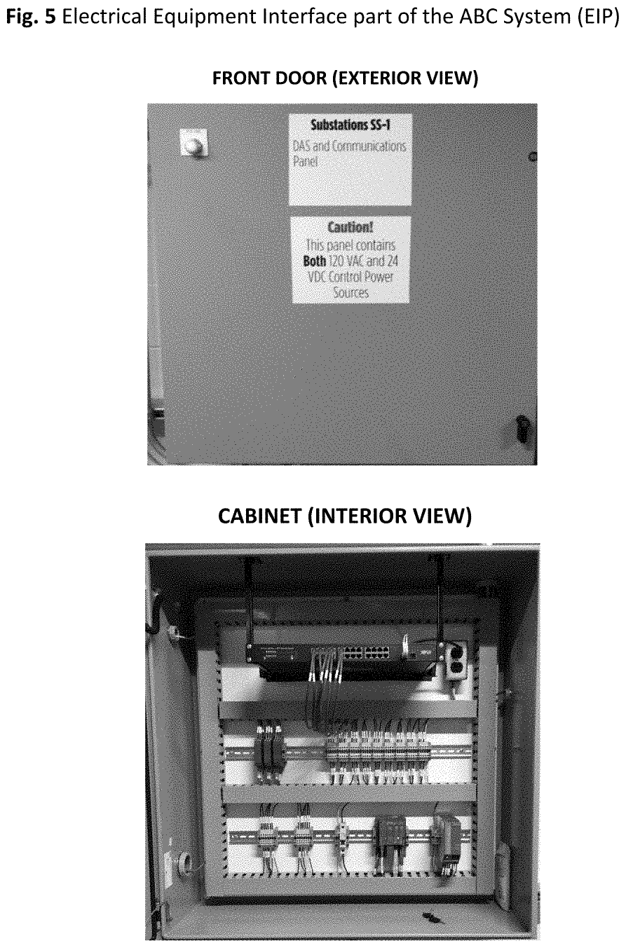

1. The present invention detects an arc flash electrical fault by calculating the rate of change in ultraviolet light, infrared light, and electrical current.

2. The devices and systems can also be controlled from a cloud-based computer which can be the host for the system operating software.

3. Provides protection for both the electrical equipment in the substation room and remote electrical systems being worked on by humans throughout the plant simultaneously.

4. The present invention also allows human interface with the arc flash mitigation system to reduce the amount of instantaneous, ground fault, short time, and long time energy from a remote location located outside the arc flash boundary where exposure to the electrical fault could produce damage to the electrical equipment and/or personal injury.

5. The present invention allows interruption of the formation of arc flash incident energy which can damage equipment or result in personal injury, thus limiting its magnitude to a value where there is little to no damage or injury.

6. The present invention is capable of detecting the inception of an impending arc flash event and providing signaling to an up-stream trip coil within 1.66 cycles of calculating an increase in the rate of change of the duv, dir and di which exceeds the user set limits.

7. The present invention is capable of detecting the onset of the arc flash incident energy and interrupting electrical current flow via a trip signal to the up-stream circuit breaker within 0.11666 seconds, or 7 cycles.

8. The present invention includes an arc flash breaker settings control system (ABC System).

9. The present invention comprises devices or systems that provide early detection and mitigation of an impending arc flash event.
